(19) United States
(12) Patent Application Publication
(10) Pub. No.: US 2008/0002515 A1
(43) Pub. Date: Jan. 3, 2008

(54) MEMORY WITH ALTERABLE COLUMN SELECTION TIME

(76) Inventors: Helmut Schneider, Munich (DE); Dominique Savignac, Ismaning (DE)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/768,160

(22) Filed: Jun. 25, 2007

(30) Foreign Application Priority Data
Jun. 24, 2006 (DE) 102006029169.7-55

(51) Int. Cl. G11C 8/00; G11C 7/00

(52) U.S. Cl. 365/233; 365/201

(57) ABSTRACT

A memory contains memory cells and is clock-controlled on the basis of a basic clock signal at the frequency f_{c}, wherein a chosen memory cell is accessed by closing an addressed column selection switch. The memory has a pulse generator to produce a column selection pulse which closes the addressed column selection switch, wherein the pulse generator contains a first pulse timer for prescribing a fixed time T_{f} for the length Tₓof the column selection pulse and a second pulse timer for prescribing a frequency-dependent time Tᵥ, which is proportional to the clock signal period T_{c}=1/f_{c}, for the length of the column selection pulse.

### CROSS-REFERENCE TO RELATED APPLICATIONS

This application claims foreign priority benefits under 35 U.S.C. §119 to co-pending German patent application number DE 10 2006 029 169.7-55, filed 24 Jun. 2006. This related patent application is herein incorporated by reference in its entirety.

### BACKGROUND OF THE INVENTION

1. Field of the Invention

The present invention relates to memory products and the operation of the same.

2. Description of the Related Art

In customary memories such as DRAM chips, the large number of binary memory cells is combined into a plurality of separate areas. Normally, the cells in each memory area form a matrix of rows and columns, and each column has an associated local read/write amplifier, subsequently referred to as “local amplifier” for short. Each of these amplifiers is connected to all the memory cells in the relevant column by means of an associated bit line. Each row can be selectively addressed by activating an associated row selection line (“word line”). The relevant activation signal is derived from a row address in a word line decoder (row decoder). The effect of activation is that each cell on the relevant line communicates its memory content to the local amplifier associated with the relevant column, which amplifier is then locked in a state in which it produces an amplified signal which represents the binary value of the stored data item.

Along each matrix row there extend one or more local data lines, and each data line is jointly associated with a plurality of local amplifiers. Each local amplifier has an individually associated column selection switch of its own which can be closed via a column selection signal in order to connect the amplifier to the associated local data line. The local data line can be connected via a line switch to an associated master data line which is common to a plurality of memory areas. Each master data line is routed to an associated “master amplifier”, which for its part is connected to an associated data connection for the purpose of outputting data which have been read and for the purpose of inputting data which is to be written.

By closing a column selection switch, the respective associated local data line and the further data path are used to set up the connection to one of the aforementioned data connections. In read mode, each closed column selection switch is used to transfer the latched data item from the addressed memory cell, amplified in the associated local amplifier, to the master amplifier, and in write mode, the data item which is input on the master amplifier is transferred via the closed column selection switch to the associated local amplifier, which then either maintains its previous latched state (when the write data item corresponds to the previous data item) or is changed over to the complementary latched state (when the write data item is different than the previous data item).

To transfer a read data item effectively from the local amplifier to the master amplifier in read mode and to latch a write data item effectively from the associated data line into the local amplifier in write mode, the associated column selection switch must respectively remain closed for a certain minimum time. When there is a given potential difference between the two defined logic levels which are intended to explicitly represent the binary data “0” and “1” on the data lines, this minimum time for the read mode is shorter the more powerful the local amplifier. However, it is not advisable to design the local amplifiers with a high gain factor in order to make said minimum time as short as possible. Powerful local amplifiers would each require a large amount of integration surface area, so that it would be a problem to accommodate them at such narrow intervals as are required by the column spacing of the memory cell matrix.

To keep down the circuit complexity, it is advantageous and also customary for the pulse duration and hence the closed time of column selection switches, subsequently referred to as “column selection time”, to be proportioned equally for read mode and write mode. The minimum duration is prescribed by design features of the memory chip, such as the gain of the local amplifiers and the charging time constants of the respective data line paths used. Each selected column selection switch is closed by a column selection pulse which, in response to an internal read or write command, is applied to a control line routed to the relevant switch and keeps this switch closed until the end of the pulse.

Like any digital circuit, memories such as DRAM chips are also subject to a clock control, where a superordinate clock signal CLK, comprising rising and falling pulse edges in regular succession, forms the time normal for the sequence of a multiplicity of individual operations and control processes. Thus, the timing of the succession of a series of read or write access operations to memory cells in the same matrix row, that is to say the “access clock”, is also controlled using this time normal. In this context, the period of the access clock, that is to say the time from one access operation to the next, is defined by a particular number of (whole or half) periods T_{C} of the superordinate clock signal CLK. That is to say that this time and hence also the maximum available total time for the duration T_{S} of a column selection pulse is proportional to the period duration T_{C} of the clock signal CLK or inversely proportional to the clock frequency F_{c}=1/T_{c}.

A memory should be able to operate correctly over a defined range of clock frequencies f_{c}. Therefore, there is a need to design an arrangement for activating the column selection in a memory chip such that it operates satisfactorily within a wide range of clock frequencies.

### SUMMARY OF THE INVENTION

According to an embodiment is accordingly a memory which contains at least one matrix of memory cells which is organized into rows and columns, and whose operation is clock-controlled on the basis of a basic clock signal at the frequency f_{c} and in which a chosen memory cell within an addressed matrix row is accessed by closing an addressed column selection switch which is associated with the matrix column containing the chosen memory cell in order to set up a connection for transferring a data bit between this cell and a data path. The embodiment provides a pulse generator which is started by a column selection command in the read mode and in the write mode of the memory chip in order to produce a column selection pulse which closes the addressed column selection switch and keeps it closed for the duration of this pulse. The pulse generator contains a first pulse timer for prescribing a fixed time T_{f} for the length Tₛ of the column selection pulse and a second pulse timer for prescribing a frequency-dependent time Tᵥ, which is proportional to the clock signal period T_{c}=1/f_{c}, for the length of the column selection pulse.

According to an embodiment, the pulse generator is in a form such that it has the first pulse timer take effect when the clock frequency f_{c} is lower than a chosen threshold value f_{TH}, and otherwise has the second pulse timer take effect.

Memories are known in which the length of the control pulse which closes the column selection switches addressed, or in other words the column selection time, is of fixed proportions. On the other hand, memory chips are also known in which the column selection time is variable and is proportioned so as to be inversely proportional to the respective clock frequency. To date, however, it has not been proposed or even merely suggested that a way be provided of changing between the two types of proportioning.

Embodiments of the invention is based on the insight that fixed proportioning of the column selection time may give rise to particular problems when the clock frequency f_{c} exceeds a certain limit and hence the duration from the start to the end of a read or write cycle is below a certain length. In this context, within each cycle, the pause after each control pulse may end up so short that there is no longer sufficient time available to produce certain charge states for terminating the cycle. A further insight is that clock-dependent proportioning of the column selection time may give rise to other problems if the clock frequency f_{c} is so low that the column selection pulse lasts much longer than is necessary for successfully reading and writing. This is undesirable for reasons of power consumption and susceptibility to interference. The reason for this is that the longer the column selection time the higher the power consumption and the greater the probability of interference signals being injected into the data transfer path too.

The controllability of the column selection time allows a memory chip to be operated over a wide range of clock frequencies to reduce the aforementioned problems.

### BRIEF DESCRIPTION OF THE DRAWINGS

The features of embodiments will become clear from the following description, taking in conjunction with the accompanying drawings. It is to be noted, however, that the accompanying drawings illustrate only typical embodiments and are, therefore, not to be considered limiting of the scope of the invention. It may admit other equally effective embodiments.

FIG. 1 shows schematically shows the data path between a memory cell and a data connection in a memory chip in connection with an embodiment of a pulse generator for column selection pulses.

FIG. 2 shows a diagram showing the signals and potential profiles for a read cycle at various locations of the arrangement shown in FIG. 1 over a common time coordinate.

FIG. 3 shows a diagram showing the signals and potential profiles for a write cycle at various locations of the arrangement shown in FIG. 1 over a common time coordinate.

FIG. 4 shows details for an embodiment of a pulse generator.

FIG. 5 shows a modified version of the pulse generator shown in FIG. 4 for performing tests on a memory chip.

FIG. 6 shows a diagram illustrating a write operation for a test mode of a memory chip.

FIG. 7 show further modification of the pulse generator shown in FIG. 5 for optional performance of burn-in tests.

FIG. 8 show further modification of the pulse generator shown in FIG. 5 for optional performance of burn-in tests.

### DETAILED DESCRIPTION OF THE PREFERRED EMBODIMENT

In the description below, the two logic potentials are denoted by H and L, where H is the “high” potential, which also represents the binary or logic value “1”, and L is the “low” potential, which is negative in comparison with H in the circuit example shown and represents the binary or logic value “0”.

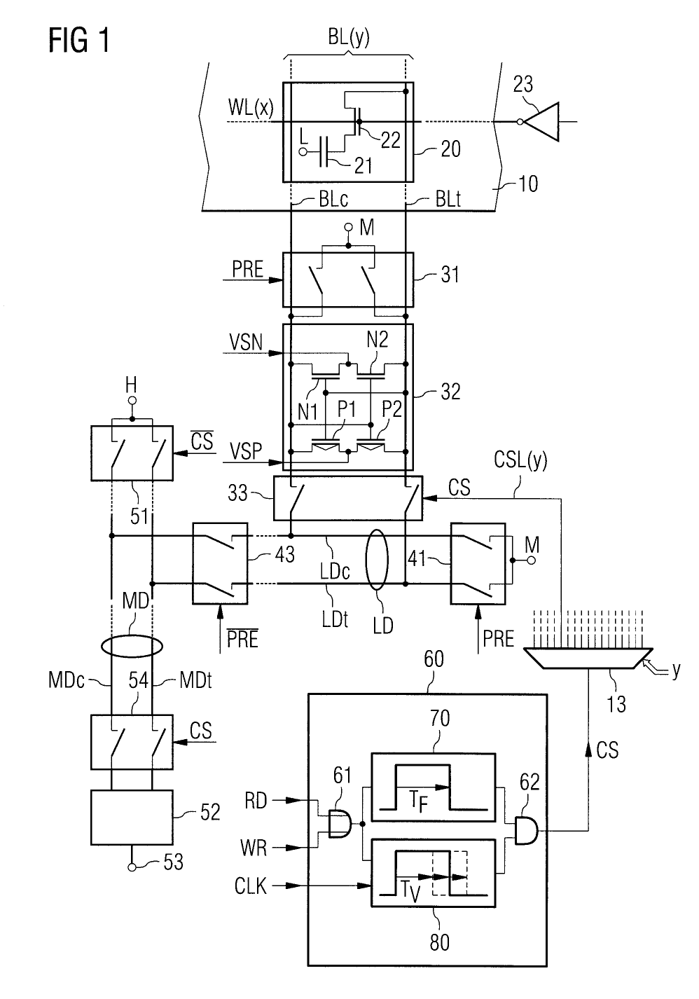

FIG. 1 shows a memory cell 20 in an arbitrary row x and any column y of a memory matrix 10 in a DRAM chip and the data transfer path between this column and a data connection 53 for the input and output of memory data. The data transfer path is part of a data path network. In this network, various local data lines LD associated with various areas or cell groups in the memory matrix can be connected via a respective selectively operable line switch 43 to a master data line MD, which for its part is connected via a master amplifier 52 to an associated data connection 53 for the input and output of memory data.

Each memory cell in the matrix 10 is designed in the same manner as the memory cell 20 shown. It contains a capacitance 21 which forms the actual memory element and whose charge state represents the binary or data value “1” or “0” (uncharged). One side of the storage capacitor 21 is at fixed potential, at L- potential in the case shown, and the other side is connected via the channel of a selection transistor 22 designed as an N-FET to one of the two wires in an associated two-wire bit line BL. The gate of the selection transistor 22 is connected to a word line WL which is associated with all the cells in the same matrix row. In the usual vernacular, one of the wires is referred to as the “true” bit line wire BLt and the other is referred to as the “complement” bit line wire BLc. In the case illustrated, the selection transistor 22 is connected to the True-bit line wire BLt, just like the selection transistors on all the other cells on the same word line WL (the manner of connection usually changes from word line to word line).

The bit line wires BLt and BLc have a local amplifier 32 with a symmetrical input and a symmetrical output connected to them. The local amplifier 32 contains a first transistor pair, comprising two p-channel field effect transistors P1 and P2, and a second transistor pair, comprising two n-channel field effect transistors N1 and N2. The source electrodes of the P-FETs P1 and P2 are coupled together at a circuit point to which a first bias voltage potential VSP can be supplied. The source electrodes of the N-FETs N1 and N2 are coupled together at a circuit point to which a second bias voltage potential VSN can be supplied. The drain electrodes of the transistors P1 and N1 and the gate electrodes of the transistors P2 and N2 are connected to the bit line wire BLt and can also be connected via a first path of a two-pole column selection switch 33 to a first wire LDt in a local data line LD. Similarly, drain electrodes of the transistors P2 and N2 and the gate electrodes of the transistors P1 and N1 are connected to the bit line wire BLc and can also be connected via the second path of the column selection switch 33 to a second wire LDc in the local data line LD.

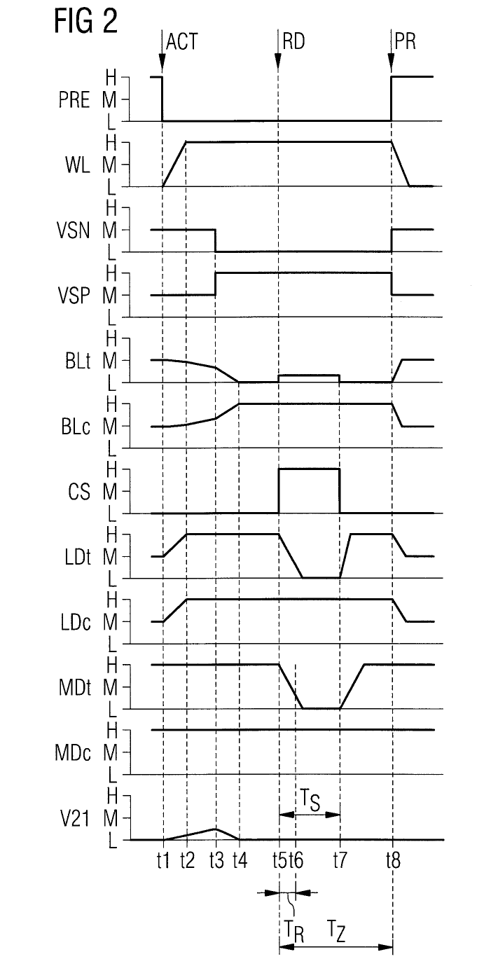

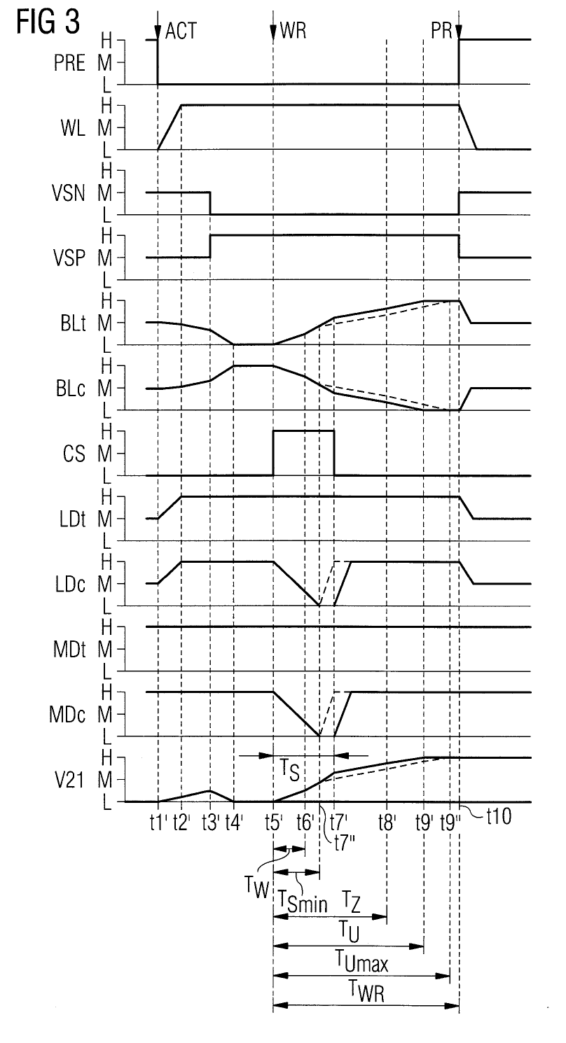

Further details from the circuit arrangement shown in FIG. 1 and also the mode for reading and writing a data item on the memory cell 20 are explained below with reference to the diagrams shown in FIG. 2 and FIG. 3. These diagrams show potential changes by virtue of rectilinear ramps for the sake of simplicity; in reality, these changes follow a respective exponential function.

First, FIG. 2 will be used to describe the preparation and performance of a read cycle. In the quiescent state, before the cell access is initiated, all the word lines are kept at L level, so that the selection transistors 22 in all the cells are off. In the quiescent state, a precharge signal PRE is also kept in the active state (i.e. at H-potential) in order to keep a precharge switch 31 closed and thereby to put both bit line wires BLt and BLc at a common precharge potential M which is as precisely as possible in the center between the L and H levels. A similar precharge switch 41, controlled by the precharge signal PRE in the same way, is situated on the wires LDt and LDc in the local data line LD so as to equalize these wires likewise at M-potential. When the precharge signal PRE is active, the line switch 43 is kept open (i.e. off or nonconductive), which is symbolized in FIG. 1 by virtue of the control signal indicated for this switch being the inverted version P̅R̅E̅ of the precharge signal.

During the quiescent state, the signals VSN and VSP are also kept at M-level, so that the local amplifier 32 is in the floating state. In the quiescent state, the column selection switch 33 is also open (i.e. off or nonconductive), so that the local amplifier 32 is isolated from the local data line LD. The open state of the line switch 43 means that the local data line LD is for its part isolated from the master data line MD. While the column selection switch 33 is open, a further precharge switch 51 on the master data line remains closed in order to keep the two wires MDt and MDc at a precharge potential equal to the H-level.

To prepare cell access, first of all, at time t1, an activation command ACT is produced, which renders the signal PRE inactive in order to open the precharge switches 31 and 41 and hence to isolate all the bit lines BL and all the local data lines LD from the precharge potential M and to close the line switch 43, so that both wires LDt and LDc in the local data line LD change to the H precharge potential of the master data lines MD. Roughly at the same time, the word line WLin a row x selected by a row address is activated, i.e. is lifted to H level, which it reaches after a certain charging time at time t2, so that the selection transistors 22 in all the memory cells 20 in the relevant row are turned on. The word line activation is effected by means of an associated word line driver 23 which is selected by a row decoder on the basis of a decoded row address x and is activated by the activation command ACT.

When the selection transistor 22 has been turned on, the bit line wire BLt receives the potential which represents the previous charge state of the cell 21 and hence the binary value of the stored data item. As an example, FIG. 2 shows the case in which the cell 20 shown from the addressed row is uncharged, that is to say stores the binary value “0”. On the associated bit line wire BLt, a small decrease in potential below the M level occurs in this case, so that BLt becomes negative in respect of BLc.

A short time later, after a safety time has elapsed at time t3, if the change in potential on the bit line wire BLt has reached a degree which can be clearly discriminated from noise phenomena, the signal VSN is switched to L level and the signal VSP is switched to H level. This turns on the local amplifier 32 by virtue of it now receiving its full supply voltage and its operating current from the sources of the two signals. If a reduction in potential has taken place on BLt, as shown in FIG. 2, then the transistors P1 and N2 are driven in the direction of increasing conductivity and the transistors P2 and N1 are driven in the direction of increasing nonconductivity, so that BLt is pulled in the direction of the L-potential and the other bit line wire BLc is pulled in the direction of the H-potential. As a result of the positive feedback between P1 and N2 and between P2 and N1 and the negative feedback between P1 and P2 and between N1 and N2, this process results in the final state being locked, so that the data value “0” is latched in the local amplifier (if the stored data item is a “1”, BLt becomes positive in respect of BLc, and the local amplifier 32 produces the opposite final state, that is to say the latching of a “1”, where BLt has been pulled to H-level and BLc has been pulled to L-level). The now “separated” potential difference between the bit line wires BLt and BLc is transferred back to the memory cell, whose memory information is refreshed in this manner. At time t4, this process is complete and the local amplifier 32 has been fully activated.

The process described above is executed simultaneously on all the columns in the addressed row, so that at time t4 the local amplifiers associated with the other columns (not shown in FIG. 1) are also in the latched state. The duration of the time period t1-t4 is a system-related waiting time for which it is necessary to wait after an activation command before a read or write mode can be started. Only after time t4 is it possible to connect a selected instance of the local amplifiers 32 for the read mode via the local data line LD and the line switch 43 to a master data line MD.

To this end, an internal read command RD is given at a time t5 and at the same time the column selection switch 33 associated with the addressed column y is closed, specifically by activating a control line CSLassociated with this switch for the duration of a column selection pulse CS. The column selection pulse CS is produced in a pulse generator 60, where it is triggered by the read command RD, and is routed via a column decoder 13 to the control line CSLselected on the basis of the column address y. The precharge switch 51 on the master data line MD is opened for the duration of the column selection pulse CS, so that the H precharge potential is decoupled from the master data line wires MDt and MDc for this duration. This is symbolized in FIG. 1 by virtue of the control signal indicated for the switch 51 being the inverted version C̅S̅ of the column selection pulse CS.

When the column selection switch 33 is closed at time t5, the potential difference H-L of the bit line wires BLt, BLc which has been “separated” in the manner described is coupled to the local data line wires LDt, LDc which are connected to the master data line wires MDt, MDc via the closed line switch 43.

To transfer the data item latched on the local amplifier 32 to the master amplifier 52, a line switch 54 which is situated between the master data line MD and the amplifier 52 is also closed for the duration of the column selection pulse CS. For the data transfer from the local amplifier 32 to the master amplifier 52, it is necessary to overcome the previous charge states of the local data line LD and of the master data line MD until the resultant potential difference on the input of the master amplifier 52 is sufficient to toggle this amplifier to a state which corresponds to the data item (indicated in FIG. 2 by a bold dot on the MDt potential profile). The charging current for this needs to be introduced by the local amplifier 32. This lasts for a certain time period t5-t6, which will be referred to here as a read switching delay T_{R}. The time period T_{R} is system-related and dependent on the power of the local amplifier, on the on-state impedances of the switches 33, 43, 54, on the charging time constants of the lines LD and MD and on the previously existing charge on these lines.

The duration T_{S} of the column selection pulse CS for the read mode therefore needs to be at least as long as T_{R}, i.e. the column selection switch 33 cannot be opened again before time t6. In the case shown, the column selection pulse CS is terminated at a somewhat later time t7.

At the end of the column selection pulse CS, that is to say as soon as the local amplifier 32 has been isolated from the data transfer path LD, MD again, the precharge switch 51 is closed again and the line switch 54 is opened again, so that both wires MDt, MDc of the master data line MD and both wires MDt, LDc of the local data line LD attempt to attain the H precharge potential again. When this potential state has been reached, a further memory cell in the same row can be read while the word line WLcontinues to remain activated and all the local amplifiers remain on. To this end, a further read command RD can be given at a time t8, which follows t7 at a sufficient interval, and this in turn produces a column selection pulse CS, but this is put onto the control line of another column selection switch in response to a new column address. The cycle described for the time period t5-t8 can be repeated a plurality of times, each time using a read command RD at time t8, with a different column address being applied each time in order to apply the column selection pulse CS for closing a respective different column selection switch (“fast-page” mode).

After one or more read cycles on the same matrix row, the entire read operation can be terminated and the quiescent state which prevailed before time t1 restored. To this end, a precharge command PR is given at time t8 at the end of the last read cycle, which activates the precharge signal PRE to H again, deactivates the word line WL to L, puts the supply potentials VSN and VSP for the local amplifier 32 (and all other local amplifiers in the same matrix area) back to M potential, opens the line switch 43 again and puts the bit line wires BLt, BLc and the local data line wires LDt, LDc back to their precharge potential M.

FIG. 3 illustrates the preparation and performance of a write cycle for the example case in which a “1” is intended to be written to the memory cell 20, which previously stored a “0”. The cell access is prepared during the time period t1′-t4′ in exactly the same way as illustrated for the time period t1 -t4 in FIG. 2, so that the same state arises at time t4′ as at time t4 shown in FIG. 2.

The write cycle is started by an internal write command WR at a time t5′. Before time t5′, that connection of the master amplifier 52 which is associated with the master data line wire MDt was set to H potential and the other connection of the master amplifier 52, which is associated with the master data line wire MDc, was set to L potential, in line with the “1” to be written. The write command WR at time t5′ starts the column selection pulse CS, so that the line switch 54 on the master amplifier 52 is closed. As a result, MDc and LDc strive for L potential, while MDt and LDt remain at H potential. Since the appearance of the column selection pulse CS also causes the column selection switch 33 to close, the previous state of the local amplifier 32 is changed over as soon as the potential difference between the wires LDt and LDc reaches the switching threshold which is required for this (indicated in FIG. 3 by a bold dot on the LDc potential profile). This lasts for a certain time period t5′-t6′, which is referred to here as write switching delay T_{W}. The time period T_{W} is system-related and longer the less powerful the master amplifier 52 and the higher the on-state impedances of the switches 33, 43, 54 and the charging time constants of the lines LD and MD and the more powerful the local amplifier.

The duration T_{S} of the column selection pulse CS for the write mode therefore needs to be at least as long as T_{W}, i.e. the column selection switch 33 cannot be opened again before time t6′. In the case shown, the column selection pulse CS is terminated at a somewhat later time T7′.

From the very start of the column selection pulse at time t5′, the closed switch 33 is used to pull the bit line wire BLt and hence also the potential V21 on the storage capacitor 21 in the cell 20 from L to H, while the bit line wire BLc is pulled from H to L. The charging current required for this is introduced, when the local amplifier 32 has toggled, both by this amplifier and by the master amplifier 52, so that the charge reversal on the bit line wires BLt and BLc occurs relatively quickly so long as the column selection pulse CS lasts.

As soon as the column selection pulse CS ends, that is to say from time t7′, the further charge reversal on the bit line BL and on the cell capacitor 21 occurs at a slower speed. That is to say that the cell charge reversal time T_{U} from the start of when the column selection switch 33 closes to time t9′, at which the charge on the cell capacitor 21 is completely reversed, is longer the shorter the time for which the column selection switch is closed (that is to say the “column selection time” T_{S}). It is equally true that the cell charge reversal time T_{U} is shorter the longer T_{S} is.

FIG. 3 uses dotted lines to show the profile of the charges on the bit line wires BLt, BLc and on the cell capacitor 21 (and also on the data lines LD and MD) for the case in which the column selection pulse CS ends at a time t7″ which is earlier than t7′. As a result of the accordingly shorter column selection time T_{S}″, the cell capacitor 21 reaches its ultimate charge state first at a later time t9″, which means a longer cell charge reversal time T_{U}″. The word line WLnaturally cannot be deactivated before the charge on the cell capacitor 21′ is completely reversed, because otherwise the selection transistors 22 on this word line would be turned off before the cell charge reversal time T_{U} has elapsed, meaning that the cell capacitor 21 would not have its charge completely reversed.

A further write cycle on another cell in the addressed matrix row can be started before the actual end t9′ of the actual cell charge reversal time T_{U}, however, e.g. at a time t8′. In this context, the word line WLcontinues to remain activated, and all the local amplifiers remain on. It is thus possible to write to further memory cells in the same row in relatively brief succession by repeating the cycle running over the time period t5′-t8′ a plurality of times, in each case starting with an internal read command WR, the column address y being changed from cycle to cycle in order to apply the column selection pulse CS to a different column selection switch each time.

If the write operation is intended to be terminated by a precharge command PR, in order to set the quiescent state, which prevailed before activation at time t1′ again, this precharge command cannot be given until after the cell charge reversal time T_{U} after the start of the last column selection pulse CS has elapsed. For this reason, the specifications for a memory chip also contain a fixed absolute time preset T_{WR} for the time period from the start of the last column selection pulse for a write operation to the output of the precharge command (Write Recovery Time). The actual cell charge reversal time T_{U} must never be longer than T_{WR}.

The precharge command PR activates the precharge signal PRE to H again, the word line WL is deactivated to L, the supply potentials VSN and VSP for the local amplifier 32 (and for all other local amplifiers in the same matrix area) are set to M potential again, the line switch 43 is opened again and the bit line wires BLt, BLc and also the local data line wires LDt, LDc are brought to their precharge potential M again.

For the time control of the read and write cycles described above, the memory chip contains a control device which produces the necessary signals in the desired chronology under the influence of a clock signal CLK. Thus, the time period t5′-t8′ and also the equally long time period t5-t8 from the start to the end of a read cycle (FIG. 2), which is subsequently referred to as the “cycle period” T_{Z} for short, are also prescribed by a fixed relation to the clock frequency, e.g. by a whole number n of half clock frequency periods T_{C}:
T_{Z}=n*T_{C}/2=n/2f_{c}.

As already mentioned further above, the pause period T_{Z}-T_{S} from the end of the column selection pulse CS (time t7 or t7′) to the end of the access cycle (time t8 or t8′) should not fall below a certain minimum measure T_{Pmin}, because otherwise the control line CSLand particularly also the data lines LD and MD would not regenerate sufficiently by the end of the cycle. When the pulse duration T_{S} is given fixed proportions, this pause becomes shorter the higher the clock frequency f_{c}. At high clock frequencies, the pause period can therefore drop below the desired minimum measure.

This danger can be reduced to some degree if it is ensured that the pulse duration T_{S} is inversely proportional to the clock frequency, that is to say changes to the same degree and in the same direction as the cycle time T_{Z}. Although the aforementioned pause period T_{Z}-T_{S} then likewise changes to the same degree, it remains at a finite value. On the other hand, however, it has been found that clock-dependent proportioning of the column selection time T_{S} is disadvantageous for the read mode if the clock frequency is relatively low. The relatively long column selection time in this case can result in leakage phenomena and the injection of interference becoming noticeable, which corrupt the data item read. There is therefore not just a minimum time T_{Smin} to be observed for the column selection pulse CS and a minimum time to be observed for the subsequent pulse pause but also a maximum time T_{Smax} for the pulse CS, which should not be exceeded if at all possible.

The general design of the pulse generator 60 which is shown in FIG. 1 allows column selection pulses CS to be produced which meet the above demands over a wide range of clock frequencies. The pulse generator 60 contains two pulse timers 70 and 80 which are both triggered via an OR gate 61 when a read command RD or a write command WR is given. The effect of the triggering is that the outputs of the two pulse timers 70 and 80 simultaneously change from L level to H level. These two outputs are routed to the inputs of an AND gate 62, whose output supplies the column selection pulse CS and, from the time at which the two pulse timers 70 and 80 are triggered, changes from L level to H level in order to start the pulse CS.

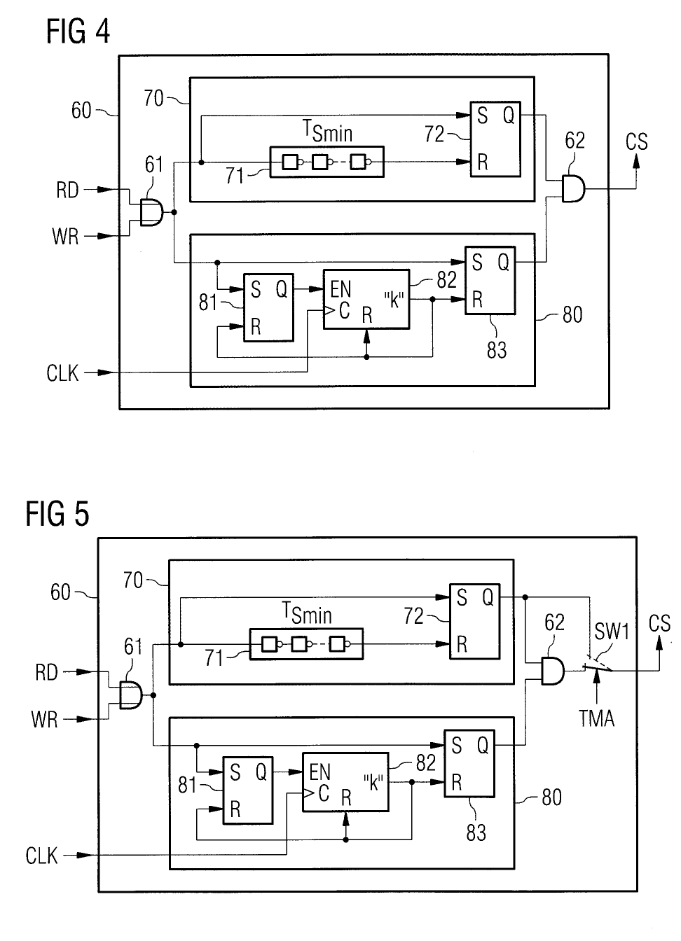

The first pulse timer 70 is designed such that its output reverts to L level again as soon as a fixed time period T_{F} has elapsed after the time of triggering. This fixed time period T_{F} is proportioned such that it is not shorter than T_{Smin}. The minimum time T_{Smin} is a variable which is dependent on the layout and on the operating voltage values and also on other operating conditions of the memory chip and can be ascertained for each chip type empirically or through simulation. In this context, it would be necessary to take account of the worst case which is to be expected, i.e. the one in which the time period for changing over the master amplifier in read mode and the time period for changing over the local amplifier in write mode are longest. In one advantageous embodiment, T_{F} is equal to T_{Smin} (as shown as an example in FIG. 4) or just slightly longer.

The second pulse timer 80 is designed such that its output reverts back to L level when a time period T_{V} since the time of triggering has elapsed which is variable and which is dependent on the frequency f_{C} of the clock signal CLK which is supplied to this pulse timer for the purpose of control. This control is effected such that the variable time T_{V} is proportional to the period duration T_{C} of the clock signal CLK, to be more precise equal to a number k>n of half clock signal periods:
Tᵥ=k*T_{C}/2.

In this case, the proportionality factor k is chosen such that T_{V} becomes equal to T_{F} when the clock frequency f_{C} decreases to such an extent that the difference T_{Z}-T_{Pmin} becomes equal to T_{F}.

As soon as the output of one of the two pulse timers reverts to L level, the output of the AND gate 62 also changes back to L level, which terminates the column selection pulse CS. The duration T_{S} of the pulse CS is thus equal to the respective shorter of the two time periods T_{F} and T_{V}. That is to say that when the clock frequency f_{C} is higher than a threshold value f_{TH} at which T_{V}=T_{F}, the duration T_{S} of the column selection pulse CS is equal to the frequency-dependent value T_{V}. Otherwise, that is to say at lower clock frequencies f_{C}≦f_{TH}, the duration T_{S} of the column selection pulse has the fixed value T_{F}.

FIG. 4 shows circuit examples of the pulse timers 70 and 80 within the pulse generator 60. The first pulse timer 70 contains, at its output, an edge-triggered RS flip-flop 72 whose set input S is connected directly to the output of the OR gate 61 and whose reset input R is connected to the output of the OR gate 61 via a delay device 71. The Q output of the flip-flop 72 is routed to the first input of the AND gate 62. The delay device 71 is formed by a chain comprising an even number of inverters, this number being chosen such that a delay equal to T_{F} is obtained.

As soon as the active edge of a read command RD or of a write command WR appears and is routed to the pulse timer 70 by the OR gate 61, the flip-flop 72 is set, so that its Q output changes from L level to H level. When the delay time T_{F} has elapsed, the flip-flop 72 is reset again by the output edge of the delay device 71. A pulse of length T_{F} thus appears at the Q output of the flip-flop.

The embodiment of the second pulse timer 80 which is shown in FIG. 4 likewise contains an edge-triggered RS flip-flop 83 at its output and also an edge-triggered RS flip-flop 81 at its input. The set inputs S of the two flip-flops 81 and 83 are connected directly to the output of the OR gate 61. The Q output of the flip-flop 81 is connected to the activation input EN of a counter 82 which counts the rising and falling edges of the clock signal CLK which is applied to its count input C. The Q output of the flip-flop 83 is routed to the second input of the AND gate 62.

As soon as the active edge of a read command RD or of a write command WR appears and is routed to the pulse timer 80 by the OR gate 61, the flip-flop 83 is set, so that its Q output changes from L level to H level. At the same time, the flip-flop 81 is also set in order to use its Q output to activate the counter 82 so that this counter counts the clock pulse edges which appear at time intervals of T_{C}/2. As soon as k edges have been counted, that is to say after a time period Tᵥ=k*T_{C}/2, a decoded count output of the counter produces an edge which is supplied to the reset input R of the flip-flop 83 in order to reset this flip-flop. Hence, a pulse of length Tᵥ=k*T_{C}/2 appears at the Q output of the flip-flop 83. At the same time as the flip-flop 83, the flip-flop 81 and the counter 82 are also reset, so that the pulse generator 60 is ready for fresh triggering by a subsequent read or write command.

The circuits shown in FIGS. 1 and 4 for a pulse generator 60 are just examples for which there are also alternatives which are likewise suitable for producing the pulses CS on the basis of the inventive principle, namely with fixed pulse duration in the case of low clock frequency and with variable, clock-dependent duration in the case of high clock frequency. Thus, the pulse timer for the fixed pulse duration can also be formed by a monostable multivibrator with a defined reset time T_{F}.

For the exemplary embodiment described, it has been assumed that both the rising and the falling edges of the clock signal can be used as “active” edges. For this reason, the numbers n and k have been defined as a number of half clock signal periods. If clock edges with just one particular polarity (rising or falling) may be active, however, the numbers n and k need to be defined as a number of whole clock signal periods.

The minimum value for the factor k is 1, and the minimum value for the factor n is accordingly equal to 2. A cycle duration T_{Z} equal to one clock signal period (that is to say equal to two half clock signal periods) is real for ordinary fast memory chips. In this case, the pulse timer for the variable pulse duration may be a simple RS flip-flop whose set input S receives the active edge of a write or read command which coincides with an active clock edge and whose reset input receives the subsequent active clock edge.

As already mentioned further above, an inventive pulse generator allowing the column selection time T_{S} to be changed between a value which is independent of the clock frequency and a value which is dependent on the clock frequency can advantageously be designed such that the memory chip can be tested inexpensively.

The usual course of a memory test is to operate the memory chip under conditions which are as similar as possible to the conditions of the subsequent use mode. In this context, the operating response is tested under the extreme conditions of the specification. One of these extreme conditions is the maximum value f_{Cmax} of the specified range of clock frequencies. The inventive pulse generator for the column selection pulses will, when operated at the maximum frequency f_{Cmax}, supply the clock-dependent pulse duration, specifically the smallest value of its envisaged value range.

At maximum clock frequency f_{Cmax} and hence with the shortest column selection time T_{Smin}, the cell charge reversal time T_{U} has the maximum value T_{Umax}. This operating condition is therefore the most critical for the T_{WR} specification. A memory test could therefore involve performing a write cycle for each memory cell, which reverses the charge on the relevant cell, at the maximum clock frequency f_{Cmax} and setting the time of the precharge command PR after the end of the cycle in each case so that the time period from the start of the column selection pulse to this time is shorter than the specified value T_{WR} by a small measure ε. In a subsequent read mode, it can then be verified whether writing has taken place correctly on all memory cells. If so, the memory chip operates satisfactorily with the T_{WR} specification, i.e. the cell charge reversal time T_{U} is shorter than T_{WR} for each memory cell.

A test of this kind is very cost-intensive because it is necessary to use a rapidly operating test appliance, which is very expensive. The pulse generator is provided with a switching device which allows the memory test to be performed at a much lower clock frequency than f_{Cmax} and still to disclose errors which would occur at maximum clock frequency. This switching device can be activated by a special test mode command in order to define the duration of the column selection pulse independently of the actual clock frequency f_{C} as being a time value which is equal to the value T_{Smin} which would be produced in use mode on the basis of frequency at maximum clock frequency f_{Cmax}.

FIG. 5 shows an exemplary embodiment of a switching device of this kind within the pulse generator 60. The switching device comprises a changeover switch SW1 which is controlled by a test mode signal TMA. During the use mode of the memory chip, the signal TMA is inactive, as a result of which the changeover switch SW1 is kept in its state shown in bold, so that the pulse generator 60 operates in exactly the same way as was described above in connection with FIG. 4. For the test mode, TMA is activated, which means that the changeover switch SW1 changes to the state shown by dashes. This decouples the CS output of the pulse generator 60 from the output of the AND gate 62 and connects it directly to the output of the first pulse timer 70, so that the length of the column selection pulse CS is determined only by this timer 70.

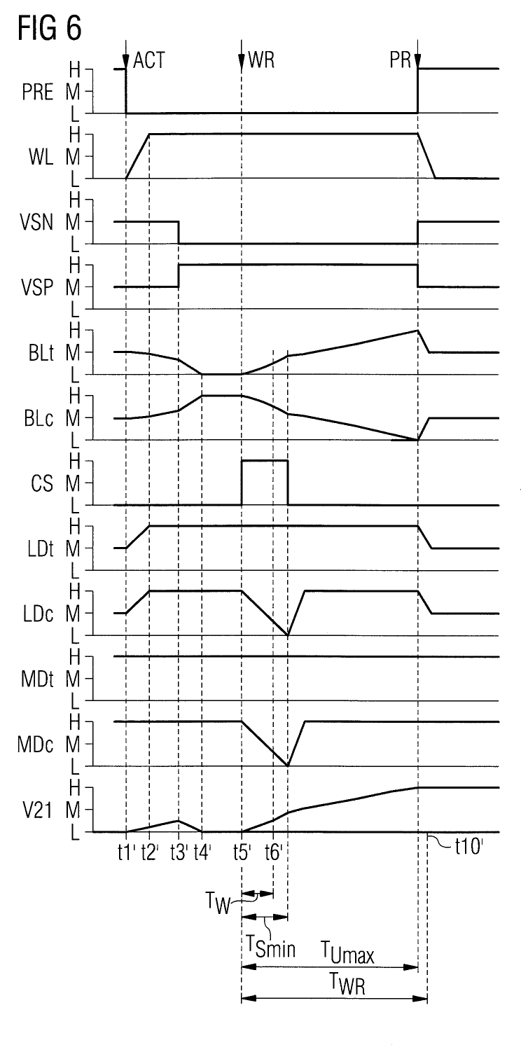

FIG. 6 shows, in the form of a similar diagram to that in FIG. 3, a write cycle for the case of a test mode in which the duration T_{S} of the column selection pulse CS is permanently set to the value T_{Smin}, e.g. using a pulse generator, as is shown in FIG. 5, when the test mode signal TMA has been activated. In line with FIG. 6, the test write mode up to toggling of the local amplifier 32 proceeds in exactly the same way as shown for the interval t1′-t6′ in FIG. 3. In test mode, the column selection pulse CS started at time t5′ ends as soon as the time period T_{Smin} has elapsed. When the memory chip is operating properly, the charge reversal on the respective addressed memory cell precisely at the end of the time period T_{Umax} (measured from the start of the column selection pulse) will be complete.

This can be checked by using a precharge command PRE precisely at the end of the time period T_{Umax} to deactivate the addressed word line, that is to say to stop any further charging possibility for the addressed memory cell, then reading the relevant memory cell again and comparing the data item which has been read with the data item written. If there is a match, it can be assumed that the write path to the relevant memory cell is in order, so that the write cycle ought to work satisfactorily even in use mode at maximum clock frequency f_{Cmax} within the specified range and with the T_{WR} specification. If there is no match, the charge reversal on the memory cell has not been able to be extensive enough, for example because the associated local amplifier is too weak.

The time period T_{Umax} which is needed when the memory chip is operating properly and for a given duration T_{Smin} of the column selection pulse CS before charge reversal on the cell capacitor 21 is complete can be discovered experimentally or through simulation.

The precharge command at the end of T_{Umax} is also used to put the supply potentials VSN and VSP for the local amplifier 32 (and for all other local amplifiers in the same matrix area) back to M potential, and likewise the bit line wires BLt, BLc and the local data line wires LDt, LDc. The line switch 43 is opened again, so that the wires MDt and MDc in the master data line also temporarily change to M potential if the column selection pulse lasts beyond the time t9″ and hence the precharge switch 51 on the master data line MD is still open. The master data line wires MDt and MDc are not brought to bear H precharge potential until the column selection pulse CS ends at a later time.

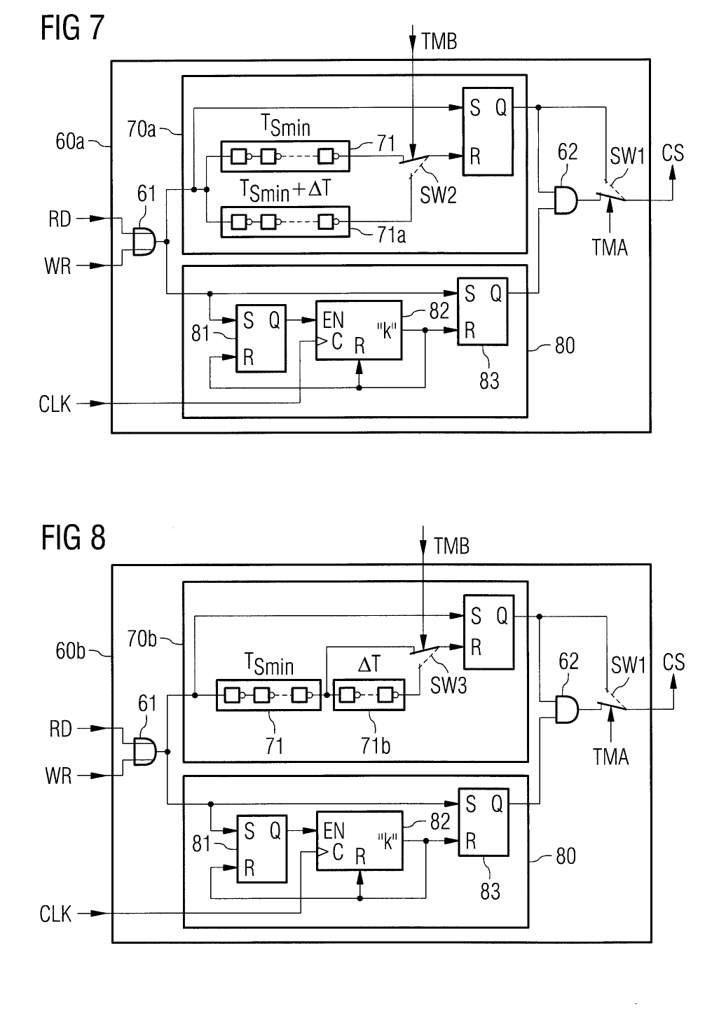

A pulse generator as shown in FIG. 5 can easily be extended in order to carry out a test mode using what is known as “burn-in” if needed. In such a test, the memory chip is artificially “stressed”, inter alia by means of increased voltages. In such a mode, the gain of the amplifiers is increased, so that it becomes more difficult for them to change over. This can cause problems particularly when writing. For this reason, it is advantageous to lengthen the fixed delay time additionally by a certain degree ΔT for the burn-in. FIGS. 7 and 8 show two exemplary embodiments of modified pulse generators which can be used to carry out a burn-in test.

The pulse generators 60a and 60b shown in FIGS. 7 and 8 differ from the pulse generator shown in FIG. 5 only through modification of the first pulse timer. In line with FIG. 7, the first pulse timer 70a contains not only the delay device 71 bringing about the fixed delay T_{Smin} but also an additional delay device 71a which brings about a delay T_{Smin}+ΔT and also a changeover switch SW2 which can be controlled by a burn-in test mode signal TMB. When the signal TMB is inactive, the changeover switch SW2 is in the state shown in bold, so that it connects the delay device 71 to the R input of the flip-flop 72. For the burn-in test, not only the signal TMA but also the signal TMB is activated, which means that the changeover switch SW2 changes to the state shown in dashes, in which it decouples the delay device 71 from the R input of the flip-flop 72 and instead couples the delay device 71a.

In the case of the pulse generator 60b shown in FIG. 8, the first pulse timer 70b contains an additional delay device 71b, bringing about a delay ΔT, in series downstream of the delay device 71 which brings about the fixed delay T_{Smin}, and also a changeover switch SW3 which can be controlled by a burn-in test mode signal TMB. When the signal TMB is inactive, the changeover switch SW2 is in the state shown in bold, which means that it connects the output of the delay device 71 to the R input of the flip-flop 72. For the burn-in test, not only the signal TMA but also the signal TMB is activated, so that the changeover switch SW3 changes to the state shown in dashes, in which it connects the output of the delay device 71b to the R input of the flip-flop 72. In comparison with the pulse generator 60a shown in FIG. 7, the pulse generator 60b shown in FIG. 8 has the advantage that the circuit complexity for the delay devices is lower and therefore less space is taken up.

It should also be mentioned that the switches shown in the figures, which are shown symbolically as mechanical switches, are in reality naturally electronic switches, advantageously formed by field effect transistors.

The preceding description describes advantageous exemplary embodiments. The features disclosed therein and the claims and the drawings can, therefore, be useful for realizing various embodiments, both individually and in any combination. While the foregoing is directed to specific embodiments, other and further embodiments may be devised without departing from the basic scope, the scope being determined by the claims that follow.

What is claimed is:

1. A memory circuit, comprising:
a plurality of memory cells whose operation is clock-controlled on the basis of a basic clock signal at the frequency f_{c}, and wherein a selected memory cell is accessed by closing an addressed column selection switch;
a pulse generator configured to produce a column selection pulse which closes the addressed column selection switch; wherein the pulse generator comprises:
a first pulse timer for prescribing a fixed time T_{f} for a length Tₛ of the column selection pulse; and
a second pulse timer for prescribing a frequency-dependent time Tᵥ, which is proportional to the clock signal period T_{c}=1/f_{c}, for the length Tₛ of the column selection pulse.

2. The memory as claimed in claim 1,
wherein the memory cells are organized into rows and columns;
wherein the operation of the memory is clock-controlled on the basis of the basic clock signal at the frequency f_{c} and in which the selected memory cell within an addressed matrix row is accessed by closing the addressed column selection switch which is associated with the matrix column containing the selected memory cell in order to set up a connection for transferring a data bit between selected memory cell and a data path; and
wherein the pulse generator is started by a column selection command in a read mode and in a write mode of the memory in order to produce the column selection pulse which closes the addressed column selection switch and keeps addressed column selection switch closed for the duration of the column selection pulse.

3. The memory as claimed in claim 1,
wherein the pulse generator has the first pulse timer take effect when the clock frequency f_{c} is lower than a chosen threshold value f_{TH}, and otherwise has the second pulse timer take effect.

4. The memory as claimed in claim 3,
wherein the column selection switch and a bit line routed to the column selection memory cell have a local amplifier arranged therebetween which, in read mode, is put into a first switching state in which the local amplifier latching a bit by a data bit stored on the addressed memory cell and, in write mode, is put into a second switching state in which the local amplifier latches a bit by a data bit transferred via the column selection switch; and further comprising:
a master amplifier at the end of a data path and which, in read mode, is put into a state in which the master amplifier latches a bit by the data bit transferred via the column selection switch; and
wherein T_{F} is at least as long as a minimum duration T_{Smin} for which the column selection switch needs to be closed in order to put the master amplifier into the respective latched state in read mode and the local amplifier into the respective latched state in write mode via the data path.

5. The memory as claimed in claim 4,
wherein T_{F} is one of (i) equal to T_{Smin} and (ii) greater than T_{Smin}.

6. The memory as claimed in claim 3,
wherein the threshold value f_{TH} is that frequency at which the frequency-dependent time T_{V} is equal to the fixed time T_{F}.

7. The memory as claimed in claim 1, wherein the first and the second pulse timer can be triggered simultaneously by the column selection command; and further comprising:
a circuit configured to start the column selection pulse at the time at which the two pulse timers are triggered and to terminate the column selection pulse when the shorter of the two times T_{V} and T_{F} elapses.

8. The memory as claimed in claim 1,
wherein the second pulse timer comprises an output flip-flop having a set input connected directly to receive a command signal edge corresponding to the column selection command and having a reset input connected to a counting circuit configured to:
start counting in response to the command signal edge in order to count successive edges of the basic clock signal and to reset the flip-flop when a preselected count value is reached.

9. The memory as claimed in claim 1,
wherein the first pulse timer comprises an output flip-flop having a set input connected directly to receive a command signal edge corresponding to the column selection command and having a reset input connected to the output of a delay device, the delay device having an input that receives the command signal edge and having a delay time equal to the duration T_{F}.

10. A memory, comprising:
a plurality of memory cells;
timing circuitry configured to control access to the plurality of memory cells; the access being clock-controlled on the basis of a basic clock signal at a frequency f_{c} and wherein a selected memory cell of the plurality of memory cells is accessed by closing an addressed column selection switch in response to a column selection pulse; the timing circuitry comprising a pulse generator to produce the column selection pulse which closes the addressed column selection switch; wherein the pulse generator comprises a test mode switching device configured to be activated by a test mode signal for the duration of a test mode of the memory in order to keep a time length Tₛ of the column selection pulse at a fixed value regardless of the clock frequency f_{c} used.

11. The memory as claimed in claim 10,
wherein the pulse generator comprises:
a first pulse timer for prescribing a fixed time T_{f} for the length Tₛ of the column selection pulse; and
a second pulse timer for prescribing a frequency-dependent time Tᵥ, which is proportional to the clock signal period T_{c}=1/f_{c}, for the length Tₛ of the column selection pulse.

12. The memory as claimed in claim 11,
wherein the fixed length of the column selection pulse, which is maintained by the test mode switching device, is a fixed time T_{f} prescribed by the first pulse timer, and
wherein the test mode switching device, when activated, is configured to connect the output of the first pulse timer to an output of the pulse generator and isolates the second pulse timer from the output of the pulse generator.

13. The memory as claimed in claim 11,
wherein the fixed length of the column selection pulse, which length is maintained by the test mode switching device, is equal to that length which becomes established as frequency-dependent value T_{V} in a use mode of the memory at the maximum value f_{Cmax} of the specified clock frequency range.

14. The memory as claimed in claim 13,
wherein the fixed length of the column selection pulse, which length is maintained by the test mode switching device, is equal to T_{Smin}.

15. The memory as claimed in claim 10,
wherein the pulse generator further comprises a circuit arrangement which can be selectively activated for a duration of the test mode in order to extend the fixed length of the column selection pulse, which length is maintained by the test mode switching device, by a fixed measure ΔT.

15. The memory as claimed in claim 10,
wherein the memory cells are organized into rows and columns,
wherein the selected memory cell within an addressed row is accessed by closing the addressed column selection switch associated with a column containing the selected memory cell in order to establish a connection for transferring a data bit between the selected memory cell and a data path; and
wherein the pulse generator is initiated by a column selection command in the read mode and in the write mode of the memory in order to produce the column selection pulse which closes the addressed column selection switch and keeps the addressed column selection switch closed for the duration of the column selection pulse.

16. A method for testing a memory, wherein the following steps are performed for a memory cell:
when a test mode signal is active, placing the memory into a write mode for performing a write operation for the memory cell in order to write a data bit to the memory cell, the write operation comprising closing a column selection switch in response to receiving a column selection pulse, wherein the column selection pulse is required, when the memory is operating properly, in order to write reliably to the memory cell;
terminating the write mode as soon as a time period from the start of the column selection pulse has elapsed; and
reading the memory cell; and
comparing a data bit which has been read out of the memory cell with the previously written data bit.

17. The method as claimed in claim 16, wherein a length of the column selection pulse is equal to that length which becomes established as a frequency-dependent value T_{V} in a use mode of the memory at a maximum value f_{Cmax} of a specified clock frequency range.

18. The method as claimed in claim 17, wherein a fixed length of the column selection pulse is equal to T_{Smin}, T_{Smin} being a minimum duration for which the column selection switch needs to be closed in order to put a respective local amplifier associated with a selected column into a respective latched state in the write mode.

19. The method as claimed in claim 16, wherein a circuit arrangement can be selectively activated for the duration of the test mode in order to extend a length of the column selection pulse by a fixed measure ΔT.
